(19) United States
(12) Patent Application Publication
(10) Pub. No.: US 2026/0118413 A1
(43) Pub. Date: Apr. 30, 2026

(54) VOLTAGE MONITORING SYSTEM FOR A SYSTEM-ON-A-CHIP

(71) Applicant: Infineon Technologies AG, Neubiberg (DE)

(72) Inventor: Peter Bogner, Wernberg (AT)

(21) Appl. No.: 19/369,733

(22) Filed: Oct. 27, 2025

(30) Foreign Application Priority Data
Oct. 31, 2024 (DE) 102024210528.7

(51) Int. Cl. G01R 31/28

(52) U.S. Cl. CPC G01R 31/2879

(57) ABSTRACT

A mechanism for performing voltage monitoring in a system-on-a-chip. The system comprises a master voltage monitor and one or more satellite voltage monitors. The master voltage monitor determines an error in a voltage reference generated by a first voltage reference generator of the master voltage monitor. The master voltage monitor is of a same type as a satellite voltage reference generator of each of one or more satellite voltage monitors. This determined error is used to correct an error in a voltage monitored by each satellite voltage monitor with reference to a satellite reference voltage produced by its respective satellite voltage reference generator.

### REFERENCE TO RELATED APPLICATION

This application claims priority to German Application number 102024210528.7, filed on Oct. 31, 2024, the contents of which are hereby incorporated by reference in their entirety.

### TECHNICAL FIELD

The present disclosure relates to systems-of-a-chip, and in particular, to voltage monitoring systems for a system-on-a-chip.

### BACKGROUND

A system-on-a-chip (SoC) is an integrated circuit that performs the function of multiple components of an electronic system using a single chip. These components may include a central processing unit (CPU), memory, input/output ports and so on. SoCs are widely used in various electronic devices, including smartphones, tablets, smart home devices, and particularly in automotive systems. A typical SoC is formed of a plurality of separate modules, each configured to provide a particular functionality to the SoC.

As SoCs become more complex and integrate an increasing number of modules, managing power distribution and consumption becomes crucial. Different modules within a same SoC may require different voltage levels to operate efficiently and reliably. There is therefore a need to perform accurate and reliable monitoring of voltage levels, particularly for calibrating and/or regulating a power provided to each module.

A typical voltage monitoring system will comprise an ADC connected to each voltage line carrying a voltage to be monitored. The reference voltage for the ADC is derived from a reference voltage generator, such as a bandgap reference. In complex SoCs, there can be a large number of voltages to be monitored (e.g., more than 10 is common).

In many applications, such as in the automotive industry, voltage monitoring forms part of a safety requirement to reduce a risk of catastrophic error and/or damage. Therefore, there is a need to provide a voltage monitoring system for a SoC that meets high accuracy requirements.

### SUMMARY

There is herein proposed a voltage monitoring system for a system-on-a-chip.

The voltage monitoring system comprises a master voltage monitor comprising a first master reference voltage generator configured to generate a first master reference voltage, wherein the first master reference voltage generator is of a first type, and an error determination system configured to determine, as a digital error, a digital representation responsive to a measure of error of the first master reference voltage.

The voltage monitoring system also includes one or more satellite voltage monitors, each satellite voltage monitor comprising a respective satellite reference voltage generator configured to generate a satellite reference voltage, wherein the satellite reference voltage generator is of the first type and is separate from the first master reference voltage generator, and a satellite voltage measurement system configured to measure, as a satellite measured voltage, a digital representation of the voltage at a satellite voltage line with respect to the satellite reference voltage.

The voltage monitoring system also comprises an error correction system communicatively connected to the error determination system of the master voltage monitor. The error correction system is configured to correct an error in the digital representation of each satellite measured voltage using the digital error.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates an existing system-on-a-chip.

FIG. 2 illustrates a system-on-a-chip with a proposed voltage monitoring system.

FIG. 3 illustrates a system-on-a-chip with another proposed voltage monitoring system.

FIG. 4 illustrates example errors in a voltage monitoring system.

### DETAILED DESCRIPTION

The examples described herein provide a mechanism for performing voltage monitoring in a system-on-a-chip. The system comprises a master voltage monitor and one or more satellite voltage monitors. The master voltage monitor determines an error in a voltage reference generated by a first voltage reference generator of the master voltage monitor. The master voltage monitor is of a same type as a satellite voltage reference generator of each of one or more satellite voltage monitors. This determined error is used to correct an error in a voltage monitored by each satellite voltage monitor with reference to a satellite reference voltage produced by its respective satellite voltage reference generator.

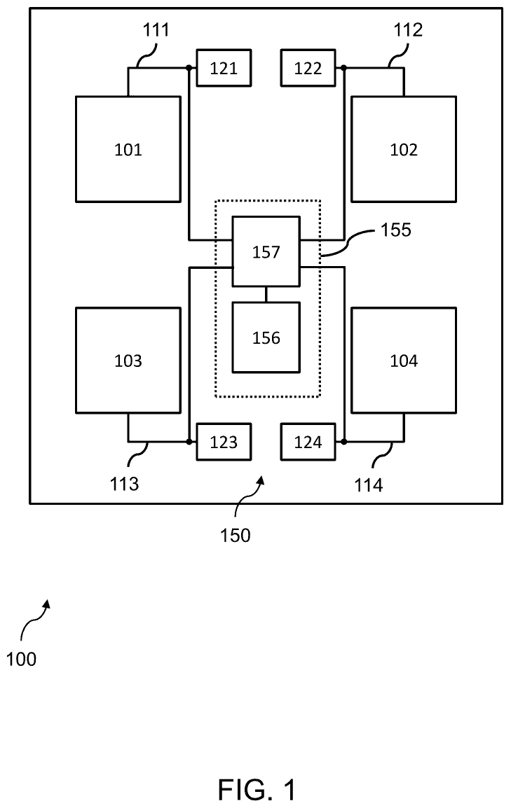

FIG. 1 schematically illustrates an existing system-on-a-chip 100 for improved contextual understanding.

The system-on-a-chip comprises a plurality of different electronic modules 101, 102, 103, 104, each of which is powered by a voltage carried by a respective voltage line 111, 112, 113, 114. The voltage on each voltage line may, for instance, be controlled by a respective voltage converter 121, 122, 123, 124. Although illustrated as a separate component for clarity, in practice, each voltage converter may form part of the respective electronic module.

Each module is designed or configured to provide a particular functionality to the system-on-a-chip. For instance, a first module may comprise a processor for providing a processing functionality, a second module may comprise a storage unit or memory for storing data; a third module may comprise a timer module; and a fourth module may comprise a communication module for communication with external devices. Of course, a single electronic module may comprise one or more sub-modules, all of which are powered from a same voltage line. Moreover, different modules may provide similar functionalities (e.g., a processing functionality) but be assigned for different purposes or needs.

Each electronic module of the system-on-a-chip may need to operate at a particular voltage level. Failure to operate a module at a required voltage level may result in improper functioning, reduced performance, or potential damage to the module. In particular, different electronic modules may require different voltage levels, such that there may be a plurality of different power domains in the system-on-a-chip.

Accordingly, there is a desire to perform accurate and high-quality monitoring and managing of voltage carried by a respective voltage line provided to each electronic module of the system-on-a-chip, to ensure reliable operation of the system-on-a-chip.

Historically, this requirement has been met using a central power management system 150. The central power management system comprises a voltage monitoring system 155 and the voltage converters 121, 122, 123, 124.

The voltage monitoring system 155 comprises a reference voltage generator 156, such as a bandgap voltage reference, that generates a reference voltage. To monitor a voltage carried by a voltage line for an electronic module, the voltage line is connected to a voltage monitor 157 (e.g., an ADC) of the voltage monitoring system by a respective voltage sensing line. The voltage at the voltage sensing line is then determined with respect to the reference voltage generated by the reference voltage generator.

The central power management system may then control or regulate the voltage at each voltage line responsive to the determined or measured voltage of each voltage line, e.g., through appropriate control of the voltage converters 121, 122, 123, 124.

In this way, a dedicated sensing line is needed to route from a voltage line of each electronic module (e.g., each power domain) to the central power management system.

The present disclosure recognizes several disadvantages with the existing approach.

In particular, each voltage line must be connected by a respective sensing line to the central power management system, which takes up valuable area of the system-on-chip, increases routing congestion and increases a complexity of the central power management system (particularly when there are a large number of voltage levels to be monitored).

Moreover, ground shifts from voltages unrelated to the power management system, such as those from high-speed input/output interfaces, are difficult or sometimes impossible to account for accurately. Existing examples of power management system will also need to be redesigned for each new product variant based on the number of voltages and any changes in the voltage domain (e.g., due to updates or upgrades to the system-on-a-chip) will also require changes in the power management system.

The present disclosure proposes an alternative approach to performing voltage monitoring within a system-on-a-chip. In particular, the present disclosure proposes an approach in which voltage monitoring functionality is distributed across the system-on-a-chip using a master-satellite architecture. In particular, a master voltage monitor determines an error in a voltage reference generated by a first voltage reference generator, which is of a same type as a satellite voltage reference generator of each of one or more satellite voltage monitors. This determined error is used to correct an error in a voltage monitored by each satellite voltage monitor.

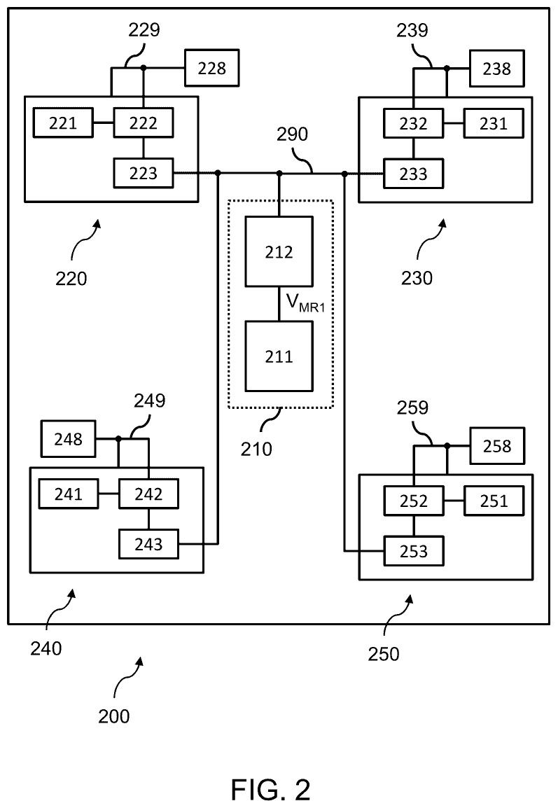

FIG. 2 illustrates an overview of a system-on-a-chip 200 comprising a proposed voltage monitoring system. The system-on-a-chip is itself a proposed embodiment, and may be formed in a single package.

The voltage monitoring system comprises a master voltage monitor 210 and one or more satellite voltage monitors 220, 230, 240, 250.

In the illustrated example, the voltage monitoring system comprises a plurality of satellite voltage monitors (namely: four satellite voltage monitors). However, the skilled person will appreciate that the voltage monitoring system may comprise any number of satellite voltage monitors, e.g., a single satellite voltage monitor, two satellite voltage monitors, three satellite voltage monitors, four satellite voltage monitors or more than four satellite voltage monitors. In particular, the voltage monitoring system may comprise a satellite voltage monitor for each power domain of the system-on-a-chip.

The master voltage generator 210 comprises a first master reference voltage generator 211 that generates a first master reference voltage VMR1. The first master voltage generator 211 also comprises an error determination system 212.

The error determination system 212 is configured to determine at least one digital error. In this context, a digital error is a digital representation responsive to a measure of error of the first master reference voltage. Suitable examples of digital errors that may be determined by the error determination system are provided later in this disclosure.

Each satellite voltage monitor 220, 230, 240, 250 is configured to monitor a voltage at a respective satellite voltage line 229, 239, 249, 259 and produce a digital representation of the measured voltage (a “satellite measured voltage”). The voltage on each respective satellite voltage line may be produced by a respective converter 228, 238, 248, 258.

More particularly, each satellite voltage monitor 220, 230, 240, 250 comprises a satellite reference voltage generator 221, 231, 241, 251 configured to generate a satellite reference voltage and a satellite voltage measurement system 222, 232, 242, 252. The satellite reference voltage generator may be of the same type as the first master reference voltage generator to ensure similar error characteristics. The satellite voltage measurement system is configured to measure the voltage at the satellite voltage line with respect to the satellite reference voltage and produce the digital representation of this measured voltage (i.e., produce the satellite measured voltage).

In this context, the “same type” refers to the satellite reference voltage generator and the first master reference voltage generator being of the same design or configuration. This means they are constructed using similar circuit topologies, components, and principles, which results in comparable performance characteristics, especially in terms of their response to environmental factors like temperature changes.

Similarly, different types of reference voltage generator (e.g., the first and second type) have different designs or configurations, meaning they are constructed using different circuit topologies, components, and/or principles.

As a simple example, the satellite voltage measurement system 222, 232, 242, 252 may comprise an analog-to-digital converter (ADC) that receives the voltage from the satellite voltage line as an input (e.g. via a sensing line). The ADC uses the satellite reference voltage as a reference for conversion, allowing it to measure the input voltage relative to the satellite reference voltage. The output of the ADC may be a digital value representing the measured voltage.

Each satellite voltage monitor may be thermally coupled to the master voltage monitor. This thermal coupling may be achieved by using a shared heat sink or other thermal management system. In this way, as the reference voltage generators of the master and satellite voltage monitors are of the same type, an error in the first master reference voltage due to thermal effects will be similar to the error in each satellite reference voltage due to thermal effects.

In some examples, the master reference voltage generator is configured to generate the master reference voltage using a chopping technique; and each satellite reference voltage generator is configured to generate each satellite reference voltage using the chopping technique. This helps ensure that temperature drift of the first master reference voltage and each satellite reference voltage match or are the same. In other words, an error in the first master reference voltage due to thermal effects will be similar to the error in each satellite reference voltage due to thermal effects when a chopping technique is employed.

Where there are a plurality of satellite voltage monitors, each satellite voltage monitor may be designed or configured to monitor a voltage for a different power domain of the system-on-a-chip. In this way, each satellite voltage line may be configured to carry a power signal for a different one of a plurality of power domains.

The voltage monitoring system also comprises an error correction system 223, 233, 243, 253 configured to correct at least one error in the digital representation of each satellite measured voltage using the at least one digital error determined by the master voltage monitor.

The error correction system may be embodied in a distributed form (as illustrated in FIG. 2) or in a centralized form (later described).

In the distributed form, each satellite voltage monitor 220, 230, 240, 250 includes its own error correction module 223, 233, 243, 253 that is integrated with the satellite voltage monitor. Accordingly, each error correction module is associated with a respective satellite voltage monitor and a corresponding satellite measured voltage. Each error correction module receives the at least one digital error from the error determination system (of the master voltage monitor) over a communication bus 290. Each error correction module then uses the received at least one digital error to correct the corresponding satellite measured voltage of its respective satellite voltage monitor. Some example approaches for correcting a satellite measured voltage are provided later in this disclosure.

It will be apparent that the error correction system (and each error correction module) functions or operates in the digital domain, and may be embodied using one or more (micro) processors or similar. Thus, the error correction system may comprise one or more processors or processing systems for processing each satellite measured voltage to produce a corrected satellite measured voltage.

By correcting errors in a distributed manner, the system can achieve more accurate voltage monitoring across multiple power domains of the system-on-chip without requiring extensive routing of sensing lines to a central location. This can help improve overall system performance and reliability.

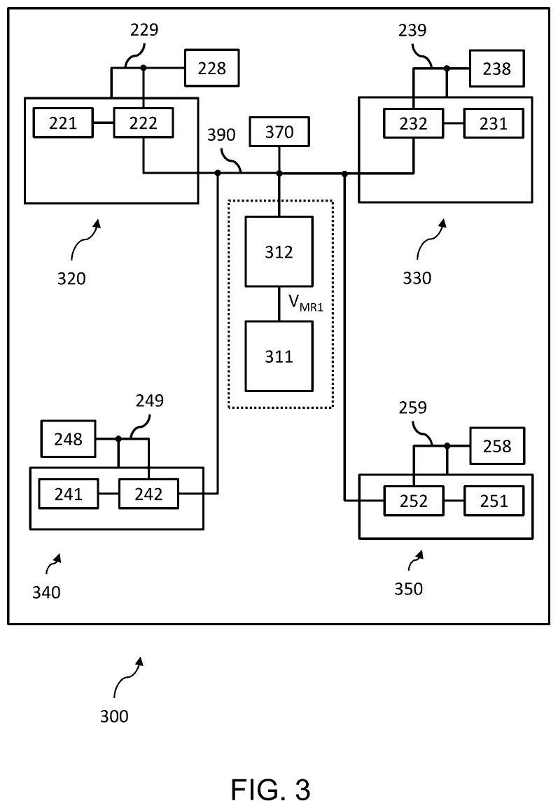

FIG. 3 illustrates an overview of a variant system-on-a-chip 300 comprising a proposed voltage monitoring system, in which the error correction system 370 is embodied as a central error correction system.

In this centralized form, the error correction system 370 may be formed its own separate module of the voltage monitoring system and/or system-on-a-chip (as illustrated in FIG. 3) or as part of the master voltage monitor

The voltage monitoring system comprises a master voltage monitor 310 and one or more satellite voltage monitors 320, 330, 340, 350, which function in a similar manner to that previously disclosed. As such, the master voltage monitor comprises a first reference voltage generator 311 and an error determination system 312.

The error correction system 370 is connected to each satellite voltage monitor 320, 330, 340, 350 via a communication bus 390. The error correction system 370 is also communicatively connected to the error determination system 312 of the master voltage monitor, which connection may be via the communication bus 390 (if the error correction system is a separate module) or another connection (if the error correction system is integrated into the master voltage monitor).

The error correction system 370 receives a respective satellite measured voltage from each satellite voltage monitor and corrects each satellite measured voltage using the at least one digital error produced by the error determination system 312.

Unless otherwise labelled above, components take the same reference numerals in FIG. 3 as their corresponding elements in FIG. 2.

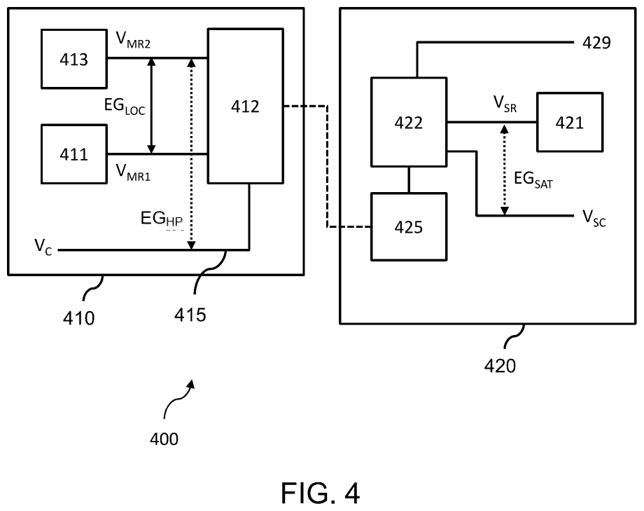

FIG. 4 conceptually illustrates errors within a voltage monitoring system 400, for the purposes of improved understanding of possible error correction techniques.

For the purposes of illustrative clarity, the illustrated voltage monitoring system 400 comprises a master voltage monitor 410 and only a single satellite voltage monitor 420. The skilled person will appreciate that, in practice, the voltage monitoring system may comprise more than one satellite voltage monitor that may be embodied in a similar manner.

As previously explained, the master voltage monitor 410 comprises a voltage reference generator 411 of a first type and an error determination system 412.

The satellite voltage monitor 420 comprises a satellite reference voltage generator 421 configured to generate a satellite reference voltage VsR and a satellite voltage measurement system 422. The satellite voltage measurement system 422 is configured to measure, as a satellite measured voltage, a digital representation of the voltage at a satellite voltage line 429 with respect to the satellite reference voltage VSR.

Here, the satellite voltage monitor 420 further comprises an error correction module 425. The error correction system is therefore configured in a distributed form. The error correction module is communicatively connected to the error determination system 412 of the master voltage monitor (e.g., over a communication bus), wherein the error correction system is configured to correct an error in the digital representation of each satellite measured voltage using the digital error.

It has been recognized that a significant source of error in a measured voltage is an error in reference voltage against which the measured voltage is defined. The present disclosure provides a number of techniques for addressing this issue to thereby improve the accuracy of voltage measurements in the voltage monitoring system. In particular, the present disclosure recognizes a variety of types of errors in the reference voltage(s) used to produce each satellite voltage measurement and proposes techniques for at least partially attenuating these errors.

A first type of error in a reference voltage results from the reference voltage being generated using a less accurate, reliable or robust reference voltage generator.

To at least partially overcome this issue, the master voltage monitor may comprise a second reference voltage generator 413 of a second type, e.g., which is less sensitive to changes in temperature than the first type (e.g., is more accurate or more robust than the first type). This second reference voltage generator 413 produces a second master reference voltage V_{MR2}. The error determination system of the master voltage monitor may then determine, as a first digital error EG_{LOC}, a digital representation of an error between the first master reference voltage V_{MR1} and the second master reference voltage V_{MR2}.

The first type of reference voltage generator is less robust (e.g., more sensitive to thermal effects or temperature drift) and/or less accurate than the second type of reference voltage generator.

The first type of reference voltage generator may, for instance, be a bandgap voltage reference; and the second type of reference voltage generator may be a high precision bandgap voltage reference. Examples of high precision bandgap voltage references are well known in the art, such as those discussed by Zhou, Ze-Kun, et al. “A resistorless high-precision compensated CMOS bandgap voltage reference.” IEEE Transactions on Circuits and Systems I: Regular Papers 66.1 (2018): 428-437 and/or Xing, Xinpeng, Zhihua Wang, and Dongmei Li. “A low voltage high precision CMOS bandgap reference.” Norchip 2007. IEEE, 2007.

In some examples, the second type of reference voltage generator has a greater footprint, i.e., occupies a greater surface area, than the first type of reference voltage generator. A larger surface area occupation is usually required by more sophisticated (and accurate) reference voltage generators.

The first digital error is then passed to the error correction system. In the distributed form of the error correction system, the first digital error may be communicated to each error correction module associated with a satellite voltage monitor via the communication bus. In the centralized form, the digital error may be provided to the central error correction system.

The first digital error is then used by the error correction module 425 (e.g., by each error correction module) to correct the/each satellite measured voltage.

As the first master reference voltage generator and the satellite reference voltage generator(s) are of a same type, it can similarly be assumed that at least some error(s) in the master reference voltage generator will also occur in the satellite reference voltage generator, particularly any errors resulting from thermal effects or temperature drift.

The first digital error may be defined as a quotient of the second master reference voltage V_{MR2} and the first master reference voltage V_{MR1}, specifically V_{MR2}/V_{MR1}. In such an example, the error correction system 425 may correct the first type of error in each satellite measured voltage by multiplying each satellite measured voltage by this quotient (V_{MR2}/V_{MR1}). Other examples for defining an error and performing an appropriate correction will be apparent to the skilled person.

By utilizing a more accurate reference voltage generator in the master voltage monitor and distributing the resulting error information, the system can compensate for inaccuracies in the less precise reference voltage generators used in the satellite voltage monitors. This approach may allow for the use of simpler, more cost-effective reference voltage generators in the satellite voltage monitors while still maintaining high overall accuracy in voltage measurements across the system-on-chip.

In some examples, the first master reference voltage generator 411 and each satellite reference voltage generator 421 are configured to generate their respective reference voltages using a chopping technique. This helps ensure that temperature drift and/or temperature inaccuracies of these reference voltage generators are the same (making the first digital error accurately representative of error due to temperature drift in each satellite reference voltage generator—as well as the first master reference voltage generator).

A second type of error in a reference voltage results from a fixed error EG_{HP} in the second master reference voltage. This holds even when the second master reference voltage is produced using an accurate or reliable reference voltage generator (e.g., a high precision bandgap reference). This fixed error represents an absolute error of the second master reference voltage with respect to an ideal voltage.

To at least partially overcome this second type of error, the error correction system may be configured to store a second digital error representing an error in the second master reference voltage. The error correction system may correspondingly be configured to use the stored second digital error to correct each measured satellite voltage.

One approach to defining the second digital error is to provide a predetermined master calibration voltage V_{C} on a master calibration voltage line 415 and measuring this voltage with respect to the second master reference voltage. This predetermined master calibration voltage may be known to the error determination system in advance (e.g., pre-programmed into the error determination system or defined by a user/operator).

The predetermined master calibration voltage may be provided, for instance, by an external high-precision voltage source connected to voltage monitoring system and/or the system-on-chip (e.g., during a calibration phase). This provides a highly accurate calibration voltage.

The master voltage monitor 410 may determine a digital representation of the voltage V_{C} on the master calibration voltage line 415 with respect to the second master reference voltage V_{MR2}. The second digital error can then be defined responsive to a difference between the predetermined master calibration voltage and the digital representation of the measured voltage. This error represents the fixed error in the second master reference voltage, which may be due to one or more systematic errors in the system.

The second digital error EG_{HP} may be defined as a ratio/quotient of the predetermined master calibration voltage V_{C} and the digital representation of the voltage on the master calibration voltage line V_{CML}, specifically V_{C}/V_{CML}. In such an example, the error correction system may correct the second type of error in each satellite measured voltage by multiplying each satellite measured voltage by this quotient (V_{C}/V_{CML}). Other examples for defining an error and performing an appropriate correction will be apparent to the skilled person.

It will be appreciated that correcting the first type of error (EG_{LOC}) and the second type of error (EG_{HP}) also functions to correct the/any fixed error in the first master reference voltage V_{MR1}.

In some examples, the master calibration voltage line may be the power line for powering the master voltage monitor, e.g., for powering at least the error determination system.

A third type of error in a reference voltage results from a fixed error EG_{SAT} in each satellite reference voltage.

To at least partially overcome this third type of error, the error correction system may be configured to store, for each satellite voltage monitor, a respective third digital error EG_{SAT} representing a fixed error in the satellite reference voltage. The error correction system may correspondingly be configured to use the stored third digital error EG_{SAT} to correct each measured satellite voltage.

One approach to defining the third digital error is to provide, for each satellite voltage monitor, a predetermined satellite calibration voltage V_{sc} on a satellite calibration voltage line for said satellite voltage monitor. Each satellite voltage monitor may measure the voltage on its respective satellite voltage line with respect to its satellite reference voltage. The/each predetermined satellite calibration voltage may be known to the error determination system in advance (e.g., pre-programmed into the error determination system or defined by a user/operator).

The predetermined satellite calibration voltage(s) may be provided, for instance, by an external high-precision voltage source connected to voltage monitoring system and/or the system-on-chip (e.g., during a calibration phase). This provides a highly accurate calibration voltage.

Each third digital error can then be defined responsive to, for each satellite voltage monitor, the difference between the predetermined satellite calibration voltage and the digital representation of the measured voltage on the satellite calibration voltage line. Each third digital error represents the fixed error in the corresponding satellite reference voltage.

For each satellite voltage monitor, the corresponding third digital error may be defined as a ratio/quotient of the predetermined satellite calibration voltage V_{SC} and the digital representation of the voltage on the satellite calibration voltage line V_{CSL}, specifically V_{SC}/V_{CSL}. In such an example, the error correction system may correct the third type of error in each satellite measured voltage by multiplying each satellite measured voltage by the corresponding quotient (V_{SC}/V_{CSL}). Other examples for defining an error and performing an appropriate correction will be apparent to the skilled person.

In some examples, for each satellite voltage monitor, the satellite calibration voltage line may be the power line for powering said satellite voltage monitor.

In some examples, when there is more than one satellite voltage monitor, the satellite calibration voltage lines of all satellite voltage monitors may be electrically connected together. In this way, the same predetermined satellite calibration voltage may be shared by each satellite voltage monitor.

In examples where both a master and a satellite calibration voltage is provided, then the satellite calibration voltage line of each satellite voltage monitor may be electrically connected to the master calibration voltage line of the master voltage monitor, such that each predetermined satellite calibration voltage is the same as the predetermined master calibration voltage.

The foregoing examples provide example approaches for determining three different digital errors (for each satellite voltage monitor), namely a first digital error EG_{LOC}, a second digital error EG_{HP} and a third digital error EG_{SAT}. The first and second digital errors are determined using the master voltage monitor, and are common to all satellite voltage monitors. The third digital error is determined using each satellite voltage monitor separately, such that each third digital error EG_{SAT} is specific to a particular satellite voltage monitor.

Where each digital error is represented by a ratio, then each corrected satellite measured voltage can be determined by multiplying said satellite measured voltage by each determined digital error (for the corresponding satellite voltage monitor).

Thus, a corrected satellite measured voltage V_{SATC} may be calculated using the following equation:

$${V}_{SATC} = {V}_{SAT} \cdot {EG}_{LOC} \cdot {EG}_{HP} \cdot {EG}_{SAT} = {V}_{SAT} \cdot {EG}_{COM} \qquad ( 1 )$$

where V_{SAT} is the satellite measured voltage, EG_{LOC} is the first digital error, EG_{HP} is the second digital error, EG_{SAT} is the third digital error and EG_{COM} is the product of the first digital error, the second digital error and the third digital error.

With reference to FIGS. 2 and 3, in some examples, the master voltage monitor may also be configured to monitor a voltage at a master voltage line, effectively performing the functions of a satellite voltage monitor in addition to its role of producing at least one digital error. This dual functionality may be achieved by incorporating appropriate additional components and circuitry within the master voltage monitor.

For instance, the master voltage monitor may include a master voltage measurement system similar to the satellite voltage measurement systems. This master voltage measurement system may be configured to measure, as a master voltage measurement, a digital representation of the voltage at a master voltage line with respect to the first master reference voltage or the second master reference voltage (if present).

The error correction system, whether in its distributed or centralized form, may be configured to receive and correct the measured voltage from the master voltage line using similar principles and techniques applied to the satellite measured voltages. This may include using the digital errors determined by the error determination system to correct any inaccuracies in the master voltage line measurement.

An error in the master voltage measurement may be corrected differently depending on which master reference voltage is used for the measurement.

For instance, when the master voltage is measured with reference to the first master reference voltage (V_{MR1}), both the fixed error (EG_{HP}) and the local error (EG_{LOC}) need to be corrected.

However, when the master voltage is measured with reference to the second master reference voltage (V_{MR2}), only the fixed error (EG_{HP}) needs to be corrected.

By incorporating this additional voltage monitoring capability, the master voltage monitor may provide voltage measurements for its own power domain, providing for more efficient use of the master voltage monitor's high-precision components and error determination capabilities, potentially reducing the overall complexity and component count of the voltage monitoring system.

In addition to the above-described examples, the following examples are disclosed.

Example 1. A voltage monitoring system for a system-on-a-chip, the voltage monitoring system comprising:
a master voltage monitor comprising:
   a first master reference voltage generator configured to generate a first master reference voltage, wherein the first master reference voltage generator is of a first type; and
   an error determination system configured to determine, as a digital error, a digital representation responsive to a measure of error of the first master reference voltage;
one or more satellite voltage monitors, each satellite voltage monitor comprising;
   a respective satellite reference voltage generator configured to generate a satellite reference voltage, wherein the satellite reference voltage generator is of the first type and is separate to the first master reference voltage generator; and
   a satellite voltage measurement system configured to measure, as a satellite measured voltage, a digital representation of the voltage at a satellite voltage line with respect to the satellite reference voltage, and
an error correction system communicatively connected to the error determination system of the master voltage monitor, wherein the error correction system is configured to correct an error in the digital representation of each satellite measured voltage using the digital error.

Example 2. The voltage monitoring system of example 1, wherein each satellite voltage monitor is communicatively connected to the master voltage monitor via a communication bus and the error correction system comprises, for each satellite voltage monitor, a respective error correction module integrated with the satellite voltage monitor, wherein the error correction module is:
communicatively connected to the error determination system of the master voltage monitor; and
configured to receive the digital error from the error determination system over the communication bus and correct an error in the digital representation of each satellite measured voltage using the digital error.

Example 3. The voltage monitoring system of example 1 or 2, wherein the error determination system of the master voltage monitor comprises:
a second master reference voltage generator configured to generate a second master reference voltage, wherein the second master reference voltage generator is of a second type that is less sensitive to changes in temperature than the first type; and
a digitization system configured to determine, as the digital error, a digital representation of a difference between the first master reference voltage and the second master reference voltage.

Example 4. The voltage monitoring system of example 3, wherein the error determination system comprises a master voltage measurement system configured to:
measure, as a first master measured voltage, a digital representation of a voltage at a first voltage line with respect to the first master reference voltage; and
measure, as a second master measured voltage, a digital representation of the voltage at the first voltage line with respect to the second master reference voltage; and wherein
the digitization system is configured to determine, as the digital error, a digital representation responsive to a difference between the first master measured voltage and the second master measured voltage.

Example 5. The voltage monitoring system of example 4, wherein the digitization system is configured to determine, as the digital error, a digital representation of the ratio between the first master measured voltage and the second master measured voltage.

Example 6. The voltage monitoring system of any one of examples 3 to 5, wherein: the first type of reference voltage generator is a bandgap voltage reference; and the second type of reference voltage generator is a high precision bandgap voltage reference.

Example 7. The voltage monitoring system of example 6, wherein:
the master reference voltage generator is configured to generate the master reference voltage using a chopping technique; and
each satellite reference voltage generator is configured to generate each satellite reference voltage using the chopping technique.

Example 8. The voltage monitoring system of any one of examples 3 to 7,
wherein the error correction system is configured to store a second digital error representing an error in the second master reference voltage,
and wherein, for each satellite voltage monitor, the error correction system is configured to further use the stored second digital error to correct the measured satellite voltage.

Example 9. The voltage monitoring system of example 8, when dependent upon example 2, wherein each satellite voltage monitor is configured to store the second digital error and each error correction module is configured to use the second digital error stored by the respective satellite voltage monitor to correct the measured satellite voltage.

Example 10. The voltage monitoring system of example 9, wherein the master voltage monitor is configured to, when a predetermined master calibration voltage is provided on a master calibration voltage line:
determine a digital representation of the voltage on the master calibration voltage line with respect to the first master reference voltage; and
define the second error responsive to a difference between the predetermined master calibration voltage and the digital representation of the determined voltage on the master calibration voltage line.

Example 11. The voltage monitoring system of any one of examples 1 to 10, wherein the error correction system is configured to, for each satellite voltage monitor:
store a third digital error representing a temperature independent error of the satellite reference voltage; and
further use the stored third digital error to correct the measure satellite voltage.

Example 12. The voltage monitoring system of example 11, wherein, for each satellite voltage monitor, when a predetermined satellite calibration voltage is provided on a satellite calibration voltage line for the satellite voltage monitor, the satellite voltage monitor is configured to:
determine a digital representation of a voltage on the satellite calibration voltage line with respect to the satellite reference voltage; and
define the third digital error responsive to a difference between the predetermined satellite calibration voltage and the digital representation of the voltage on satellite calibration voltage line.

Example 13. The voltage monitoring system of example 12, wherein, when there is more than one satellite voltage monitor, the satellite calibration voltage lines of all satellite voltage monitors are electrically connected together, such that the same predetermined satellite calibration voltage is shared by each satellite voltage monitor.

Example 14. The voltage monitoring system of any of examples claim 12 or 13, when dependent upon example 10, wherein the satellite calibration voltage line of each satellite voltage monitor is electrically connected to the master calibration voltage line of the master voltage monitor, such that the predetermined satellite calibration voltage is the same as the predetermined master calibration voltage.

Example 15. The voltage monitoring system of any one of examples 1 to 14, wherein the one or more satellite voltage monitors comprises two or more satellite voltage monitors.

Example 16. A system-on-a-chip comprising a single package containing the voltage monitoring system of any one of examples 1 to 15.

Example 17. The system-on-a-chip of example 16 comprising a plurality of power domains, wherein each satellite voltage line is configured to carry a power signal for a different one of the plurality of power domains.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the systems including its preferred embodiments as outlined in the present document may be used stand-alone or in combination with the other systems disclosed in this document. Furthermore, all aspects of the systems outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A voltage monitoring system for a system-on-a-chip, the voltage monitoring system comprising:
a master voltage monitor comprising:
a first master reference voltage generator configured to generate a first master reference voltage, wherein the first master reference voltage generator is of a first type; and
an error determination system configured to determine, as a digital error, a digital representation responsive to a measure of error of the first master reference voltage;
one or more satellite voltage monitors, each satellite voltage monitor comprising;
a respective satellite reference voltage generator configured to generate a satellite reference voltage, wherein the satellite reference voltage generator is of the first type and is separate from the first master reference voltage generator; and
a satellite voltage measurement system configured to measure, as a satellite measured voltage, a digital representation of the voltage at a satellite voltage line with respect to the satellite reference voltage, and
an error correction system communicatively connected to the error determination system of the master voltage monitor, wherein the error correction system is configured to correct an error in the digital representation of each satellite measured voltage using the digital error.

2. The voltage monitoring system of claim 1, wherein each satellite voltage monitor is communicatively connected to the master voltage monitor via a communication bus and the error correction system comprises, for each satellite voltage monitor, a respective error correction module integrated with the satellite voltage monitor, wherein the error correction module is:
communicatively connected to the error determination system of the master voltage monitor; and
configured to receive the digital error from the error determination system over the communication bus and correct an error in the digital representation of each satellite measured voltage using the digital error.

3. The voltage monitoring system of claim 1, wherein the error determination system of the master voltage monitor comprises:
a second master reference voltage generator configured to generate a second master reference voltage, wherein the second master reference voltage generator is of a second type that is less sensitive to changes in temperature than the first type; and
a digitization system configured to determine, as the digital error, a digital representation of a difference between the first master reference voltage and the second master reference voltage.

4. The voltage monitoring system of claim 3, wherein the error determination system comprises a master voltage measurement system configured to:
measure, as a first master measured voltage, a digital representation of a voltage at a first voltage line with respect to the first master reference voltage; and
measure, as a second master measured voltage, a digital representation of the voltage at the first voltage line with respect to the second master reference voltage; and wherein
the digitization system is configured to determine, as the digital error, a digital representation responsive to a difference between the first master measured voltage and the second master measured voltage.

5. The voltage monitoring system of claim 4, wherein the digitization system is configured to determine, as the digital error, a digital representation of the ratio between the first master measured voltage and the second master measured voltage.

6. The voltage monitoring system of claim 3, wherein:
the first type of reference voltage generator is a bandgap voltage reference; and
the second type of reference voltage generator is a high precision bandgap voltage reference.

7. The voltage monitoring system of claim 6, wherein:
the master reference voltage generator is configured to generate the master reference voltage using a chopping technique; and
each satellite reference voltage generator is configured to generate each satellite reference voltage using the chopping technique.

8. The voltage monitoring system of claim 3, wherein the error correction system is configured to store a second digital error representing an error in the second master reference voltage,
and wherein, for each satellite voltage monitor, the error correction system is configured to further use the stored second digital error to correct the measured satellite voltage.

9. The voltage monitoring system of claim 8, wherein each satellite voltage monitor is communicatively connected to the master voltage monitor via a communication bus and the error correction system comprises, for each satellite voltage monitor, a respective error correction module integrated with the satellite voltage monitor, wherein the error correction module is:
communicatively connected to the error determination system of the master voltage monitor; and
configured to receive the digital error from the error determination system over the communication bus and correct an error in the digital representation of each satellite measured voltage using the digital error,
wherein each satellite voltage monitor is configured to store the second digital error and each error correction module is configured to use the second digital error stored by the respective satellite voltage monitor to correct the measured satellite voltage.

10. The voltage monitoring system of claim 9, wherein the master voltage monitor is configured to, when a predetermined master calibration voltage is provided on a master calibration voltage line:
determine a digital representation of the voltage on the master calibration voltage line with respect to the first master reference voltage; and
define the second error responsive to a difference between the predetermined master calibration voltage and the digital representation of the determined voltage on the master calibration voltage line.

11. The voltage monitoring system of claim 1, wherein the error correction system is configured to, for each satellite voltage monitor:
store a third digital error representing a temperature independent error of the satellite reference voltage; and
further use the stored third digital error to correct the measure satellite voltage.

12. The voltage monitoring system of claim 11, wherein, for each satellite voltage monitor, when a predetermined satellite calibration voltage is provided on a satellite calibration voltage line for the satellite voltage monitor, the satellite voltage monitor is configured to:
determine a digital representation of a voltage on the satellite calibration voltage line with respect to the satellite reference voltage; and
define the third digital error responsive to a difference between the predetermined satellite calibration voltage and the digital representation of the voltage on satellite calibration voltage line.

13. The voltage monitoring system of claim 12, wherein, when there is more than one satellite voltage monitor, the satellite calibration voltage lines of all satellite voltage monitors are electrically connected together, such that the same predetermined satellite calibration voltage is shared by each satellite voltage monitor.

14. The voltage monitoring system of claim 1, wherein the master voltage monitor, the one or more satellite voltage monitors, and the error correction system are implemented in a single package of a system-on-a-chip.

15. The voltage monitoring system of claim 14 comprising a plurality of power domains, wherein each satellite voltage line is configured to carry a power signal for a different one of the plurality of power domains.

16. A satellite voltage monitoring system, comprising
a satellite reference voltage generator configured to generate a reference satellite voltage;
a satellite voltage measurement system configured to generate a digital representation of a satellite voltage based on the satellite reference voltage; and
an error correction system, configured to
receive a digital error from a master voltage monitor error determination system, the digital error indicative of an error of a master reference voltage; and
correct the digital representation of the satellite voltage based on the digital error.

17. The satellite voltage monitoring system of claim 16, wherein the digital error comprises a first digital error indicative of an error between a master reference voltage generated by a voltage generator of the same type as the satellite voltage generator and a second master reference voltage generated by a different master reference voltage generator.

18. The satellite voltage monitoring system of claim 17, wherein the digital error comprises a second digital error indicative of an error between the second master reference voltage and a calibration voltage.

19. The satellite voltage monitoring system of claim 18, wherein the digital error comprises a first ratio indicative of a ratio between the master reference voltage and the second master reference voltage and a second ratio indicative of the error between the second master reference voltage and the calibration voltage.

20. The satellite voltage monitoring system of claim 16, wherein the error correction system is configured to correct the digital representation of the satellite voltage based on a second digital error indicative of an error between the satellite reference voltage and a satellite calibration voltage.
